(19) United States
(12) Patent Application Publication
(10) Pub. No.: US 2025/0387867 A1
(43) Pub. Date: Dec. 25, 2025

(54) WAFER PROCESSING MACHINE WITH AUXILIARY WORKSTATIONS

(71) Applicant: Lapmaster International, LLC, Mt. Prospect, IL (US)

(72) Inventors: Robert Lewis Rhoades, Fishers, IN (US); Ian Currier, Rutherfordton, NC (US); Czeslaw Gibas, Norwood Park, IL (US); Isaak Garbar, Vernon Hills, IL (US)

(73) Assignee: Lapmaster International, LLC, Mt. Prospect, IL (US)

(21) Appl. No.: 19/247,950

(22) Filed: Jun. 24, 2025

Related U.S. Application Data
(60) Provisional application No. 63/663,947, filed on Jun. 25, 2024.

(51) Int. Cl. B24B 37/04; H01L 21/04; H01L 21/304; H01L 21/306

(52) U.S. Cl. CPC B24B 37/04; H01L 21/0475; H01L 21/304; H01L 21/30625

(57) ABSTRACT

A semiconductor wafer processing machine is configured to include at least one wafer grinding station and at least one auxiliary processing station. In one form the machine includes a rotary indexing table to move a semiconductor wafer between a first grinding station and a second grinding station. A first auxiliary processing station is configured to conduct a first auxiliary processing operation on the semiconductor wafer. A second auxiliary processing station is configured to conduct a second auxiliary operation on the semiconductor wafer. In an embodiment, the first and second auxiliary processing stations can be associated with a slurry introduction systems for introduction of a liquid slurry.

### CROSS REFERENCE TO RELATED APPLICATIONS

Pursuant to 35 U.S.C. § 119(e), this application claims priority to U.S. provisional application No. 63/663,947 filed on Jun. 25, 2024, the disclosure of which is incorporated by reference in its entirety for all purposes.

### BACKGROUND

Integrated circuits and other semiconductor devices are fabricated from semiconductor wafers, which are thin, planar slices cut or sliced from a solid crystalline ingot or boule grown from a liquid semiconductor material. After slicing, the semiconductor wafers are prepared through a series of surface processing steps to achieve the desired dimensions, surface finishes, and mechanical characteristics. The surface processing steps may occur during the wafer manufacturing sequence prior to the formation of circuitry on a planar surface of the wafer or may occur in a back-thinning process after circuits are fabricated to achieve a desired thickness and for stress relief prior to wafer dicing.

The plurality of surface processing steps may be differentiated to produce specific characteristics and achieve specific goals during manufacturing, such as achieving the desired thickness and surface parallelism while maintaining or producing desired mechanical properties. By way of example, the semiconductor wafers may have an initial thickness of approximately 750 μm during circuit fabrication, which may be reduced to a finished thickness of 100 μm or less prior to wafer dicing in preparation for final packaging. Currently, the surface processing steps must produce the desired surface finish of the semiconductor wafer while avoiding excess damage or imparting unnecessary stresses to the wafer. Specialized or customized machines have been constructed for efficiently conducting the differentiated wafer processing steps.

Silicon carbide (SiC) is gaining popularity as a semiconductor material for a variety of semiconductor devices. However, among naturally occurring materials, SiC has a hardness value second only to diamond. This makes the fabrication of semiconductor wafers made from SiC slow and expensive. For example, the customized tooling for the surface processing steps may become quickly worn or dulled due to the hardness of SiC material. The present disclosure is directed to a wafer processing machine and arrangement for the efficient processing of semiconductor wafers, including those made from harder materials such as SiC.

### SUMMARY OF THE DISCLOSURE

The arrangement of the present disclosure provides a wafer processing machine with increased functionality and improves utility for the surface processing of semiconductor wafers including those produced from harder materials such as SiC. The wafer processing machine includes a plurality of processing stations that are included or integrated within a common machine base in a fixed arrangement to establish a workflow for the continuous and sequential processing of a plurality of semiconductor wafers. The plurality of integrated processing stations can be assigned or configured to progressively conduct different and specific surface processing operations on planar surfaces of the semiconductor wafer, producing a finished, polished wafer ready for subsequent microfabrication and etching of electronic circuitry thereon. The plurality of processing stations in a common machine base enable variable and versatile arrangements of surface processing steps with different abrasives, contact pressures, and removal rates. Furthermore, the processing stations can be arranged to concurrently and cooperatively process several semiconductor wafers increasing throughput. The wafer processing machine may be fully automated via industrial programmable logic controllers utilizing computer numerical control programming to continuously process the semiconductor wafers through the plurality of processing stations.

In an embodiment, the wafer processing machine may include at least one wafer grinding station to perform a grinding operation and at least one auxiliary processing station to perform an auxiliary processing operation.

In an embodiment, the wafer processing machine can include two grinding stations that are fixedly supported on the machine base and configured to conduct respective grinding operations on the semiconductor wafer. The grinding stations can be located adjacent to a rotary indexing table rotatably disposed in the machine base and rotatable with respect to the central table axis. Semiconductor wafers can be held on a plurality of wafer-holding chucks mounted on the rotary indexing table that, when rotated, move the wafers between the first and second grinding stations, for example, to sequentially conduct a rough grinding operation and a fine grinding operation on an individual wafer.

To improve surface processing, the wafer processing machine can include one or more auxiliary processing stations that are physically fixed or integrated into the machine base and arranged with respect to the workflow to conduct pre-grinding or post-grinding operations on the semiconductor wafer. For example, a first auxiliary processing station can be located with respect to the rotary indexing function to conduct a preliminary lapping operation to remove saw marks or other rough topography remnants from slicing of the semiconductor wafer from an ingot. If such surface features remain present on the wafer surface during the grinding operations, they can cause excessive wear of the grinding wheels, thus shortening the operative life and increasing the processing cost per semiconductor wafer. In an embodiment, the first auxiliary processing station can include an attachable tool pad with either integrated diamond bits or tiny abrasive particles suspended in a liquid vehicle that is dispensed onto a polymer pad to mechanically lap or rough polish the planar surface of the semiconductor wafers.

To improve the condition of the semiconductor wafer after the grinding process, the second auxiliary processing station can receive the ground wafers and conduct a subsequent polishing operation. The polishing operation can remove or reduce a significant portion of the post-grinding damage remaining on the semiconductor wafer after the abrasive grinding operations. For example, the polishing operation can produce a highly polished, mirror-like finish on the planar surface of the semiconductor wafer and can relieve residual stresses or the like imparted during the grinding operation, thus reducing the likelihood of wafers cracking or becoming damaged during subsequent handling and microfabrication. In an embodiment, the second auxiliary processing station can be configured to conduct a chemical-mechanical polishing operation (CMP).

CMP is technique utilizing both chemical and mechanical forces to polish the wafer surface and may involve the introduction of a corrosive and abrasive liquid slurry that is brought into contact with the semiconductor wafer by relative rotation with respect to a polishing pad. The CMP slurry can chemically react with the semiconductor wafer to chemically alter or soften the surface and abrasive particles therein create friction that can mechanically polish the planar surface through relative rotation while in abutting contact with the polishing pad.

An advantage of the disclosed arrangement for the wafer processing machine is the increased throughput by arranging the plurality of processing stations to simultaneously conduct different surface processing operations. The individual semiconductor wafers can be progressively transferred through each of the processing stations with each conducting a unique surface processing operation to progressively finish the wafer. The combined totality of the unique operations enables surface processing of harder semiconductor material, including SiC, with the individual processing stations configured and tailored for distinct operations operating in a cooperative manner that optimizes overall performance. Moreover, the sequential arrangement of the processing stations allows multiple semiconductor wafers to be concurrently processed at the different stations.

### BRIEF DESCRIPTION OF THE DRAWINGS

FIG. 1 is a front perspective view of a wafer processing machine having a plurality of workstations within the machine bed for the automated processing of a planar surface of a semiconductor wafer.

FIG. 2 is perspective view of an auxiliary workstation for pre-processing or post-processing of the semiconductor wafer showing a processing arm positioned in operative association with respect to a wafer support plate.

FIG. 3 is a perspective view of the auxiliary workstation showing the processing arm out of operative association with the wafer support plate.

FIG. 4 is a top perspective view of the wafer processing machine of the preceding Figures.

FIG. 5 is a schematic diagram illustrating an exemplary embodiment of the automated workflow of the semiconductor wafer through the plurality of processing stations.

### DETAILED DESCRIPTION

In accordance with the following detailed description and as shown in the accompanying drawings, the disclosure describes a wafer processing machine for surface grinding a planar semiconductor wafer that includes a machine base extending along a longitudinal axis between a forward longitudinal end and a rearward longitudinal end and a rotary indexing table disposed in and rotatable with respect to the machine base about a fixed central table axis perpendicular to the longitudinal axis, the rotary index table including a plurality of wafer-holding chucks each for accommodating a wafer. The wafer processing machine includes a first wafer grinding station and a second wafer grinding station disposed on and fixed to the machine base, the first and second wafer grinding stations located between the rotary indexing table and the rearward longitudinal end of the machine base, the first and second wafer grinding stations configured to respectively conduct a first and second surface grinding operations on the semiconductor wafer accommodated on the rotary indexing table. The wafer processing machine also includes a first auxiliary processing station and a second auxiliary processing station disposed on and integrally fixed to the machine base, the first and second auxiliary processing stations located between the rotary indexing table and the forward longitudinal end of the machine base, the first and second auxiliary processing stations configured to respectively conduct a first and second auxiliary operation on the semiconductor wafer.

In another aspect, the wafer-holding chucks of the rotary indexing table can be movably rotated and selectively repositioned for operative alignment with the first wafer grinding station, the second wafer grinding station, and a wafer loading/unloading position.

In another aspect, the first and second wafer grinding stations and the first and second auxiliary processing stations are laterally opposite and offset from the longitudinal axis of the machine base.

In another aspect, the first and second auxiliary processing stations each include a wafer support table and rotating tool that can conduct respectively the first or second auxiliary operation on the semiconductor wafer accommodated on a wafer support table.

In another aspect, the first and second auxiliary processing stations each include a processing arm attached to the rotatable tool and that pivots with respect to the wafer table.

In another aspect, each wafer support table includes ports operably associated with a suction or vacuum feature for releasably securing the semiconductor wafer during the respective first and second auxiliary operations.

In another aspect, the first and second auxiliary processing stations each include an attachable tool pad that is attachable to the rotatable tool.

In another aspect, the first and second auxiliary processing stations each include a dressing station for periodically redressing the attachable tool pad.

In another aspect, the dressing station is supported on a support arm to be vertically coplanar with the wafer support table.

In another aspect, the first auxiliary processing station is configured to conduct a lapping operation on the semiconductor wafer prior to transfer to the rotary indexing table.

In another aspect, the second auxiliary processing station is configured to conduct a polishing operation on the semiconductor wafer after transfer from the rotary indexing table.

In another aspect, the wafer processing machine further comprises a wafer-transfer robot for transferring the semiconductor wafer between the wafer loading/unloading position of the rotary indexing table, the first auxiliary processing station and the second auxiliary processing station.

In another aspect, the wafer processing machine further comprises a cassette station located at the forward longitudinal end of the machine base.

In another aspect, the wafer processing machine further comprises a cleaning station located longitudinally between the second auxiliary processing station and the cassette station.

In another aspect, the wafer processing machine further comprises an alignment station located longitudinally between the first auxiliary processing station and the cassette station.

In another aspect, the cassette station, the alignment station, the first auxiliary processing station, the second auxiliary processing station, and the cleaning station are all disposed in a working envelope of the wafer-transfer robot.

The disclosure also describes a method of processing a planar semiconductor wafer through a wafer processing machine. The method may involve in any order:
(a) transferring the semiconductor wafer from a wafer cassette station to a first auxiliary processing station for conducting a first auxiliary process with a first rotatable tool
(b) transferring the semiconductor wafer from the first auxiliary processing station to a wafer-holding chuck on a rotary indexing table;
(c) indexing the rotary indexing table to rotate the semiconductor wafer to a first wafer grinding station to conduct a first grinding operation;
(d) indexing the rotary indexing table to rotate the semiconductor wafer to a second wafer grinding station to conduct a second grinding operation;
(e) transferring the semiconductor wafer from the rotary indexing table to a second auxiliary processing station for conducting a second auxiliary process with a second rotatable tool; and
(f) transferring the semiconductor wafer from the second auxiliary processing station to the wafer cassette station.

In another aspect, the first auxiliary operation is a lapping operation conducted by the first auxiliary processing station on the semiconductor wafer.

In another aspect, the second auxiliary operation is a polishing operation conducted by the first auxiliary processing station on the semiconductor wafer.

In another aspect, the method involves a wafer-transfer robot that transfers the semiconductor wafer between the loading/unloading position of the rotary indexing table, the first auxiliary processing station and the second auxiliary processing station.

In another aspect, the method involves cleaning the semiconductor wafer during the transfer between the second auxiliary processing station and the wafer cassette station.

In another aspect, the method involves aligning the semiconductor wafer during the transfer between the wafer cassette station and the first auxiliary processing station.

In another aspect, the method involves unloading a semiconductor wafer from a wafer cassette at a cassette station prior to transferring the semiconductor wafer to the first auxiliary processing station and loading the semiconductor wafer to a wafer cassette at the wafer cassette station after transferring the semiconductor wafer from the second auxiliary processing station.

In another aspect, the method involves periodically dressing the first rotatable tool with a first dressing station supported on the first auxiliary processing station and periodically dressing the second rotatable tool with a dressing station supported on the second auxiliary processing station.

In another aspect, the method involves securing by suction the semiconductor wafer to a wafer support plate of the first auxiliary processing station during the first auxiliary operation and securing by suction the semiconductor wafer to a wafer support plate of the second auxiliary processing station during the second auxiliary operation.

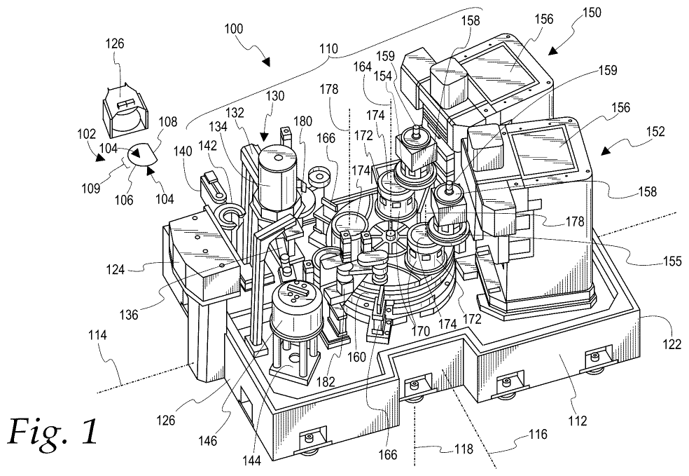

The preceding aspects of the disclosure will now be described with reference to the drawings, where whenever possible like reference numbers will refer to like elements. There is illustrated in FIG. 1 a wafer processing machine 100 for conducting a continuous series of surface processing steps on workpieces such as a semiconductor wafer 102. The thin, flat semiconductor wafers 102 are macroscopically planar and may be sliced from a larger cylindrical boule or ingot of a crystalline semiconductor material such as silicon carbide (SiC). The wafer 102 can be generally circular in shape with opposing first and second planar wafer surfaces 104 parallel to each other and circumscribed by a circular peripheral wafer edge 106 that outlines the workpiece. To facilitate locating and orientation of the wafer 102 during processing and fabrication, a flat 108 may be formed onto the otherwise circular peripheral wafer edge 106. The semiconductor wafer 102 has a wafer thickness 109 dimensionally defined between the opposed planar wafer surfaces 104. The wafer processing machine 100 is configured to produce the desired wafer thickness 109 of the semiconductor wafer 102 and the surface finish of the planar surfaces 104 through a series of surface processing steps.

To concurrently conduct the different surface processing steps, the wafer processing machine 100 may be unitary in construction with a plurality of differentiated processing stations 110 that are commonly included and integrated into a machine base 112. The processing stations 110 can be differentiated and designed to conduct specific surface processing operations on the semiconductor wafer 102. The different processing operations can be reassigned or rearranged with respect to the plurality of processing stations 110 for variability and versatility, for example, to accommodate wafers of different materials or physical characteristics. The wafer processing machine 100 can include a plurality of external panels and/or doors to enclose the internal operations, which are not shown in the Figures for visibility. The processing operations conducted by the plurality of integrated processing stations can be automated by an industrial programmable logic controller (PLC) responsive to computer numerical controlled programming. To interface with an operator, the wafer processing machine 100 can include a human-machine interface (HMI) including visual display screens and keyboards or buttons for input/output functionality. The unitary arrangement of the wafer processing machine 100 facilitates interfacing with electrical, pneumatic, vacuum and/or hydraulic systems and the organized distribution of motive power from those systems to the plurality of processing stations 110. The wafer processing machine 100 can include a control cabinet to receive power lines, data cables, fluid conduits and hoses, etc., and that can house the valves, meters, switches, and other controls for those systems.

The machine base 112 can be a structural bed that supports the plurality of processing stations 110 in a determined fixed arrangement, thereby organizing the workflow of the different operations for surface processing of the semiconductor wafers 102. The machine base 112 can be a low, flat, and rectangular structure, and can be configured to be set on the shop floor of a wafer fabrication facility. For referential purposes, the machine base 112 can be associated with a Cartesian coordinate system of multiple intersecting axes including a longitudinal axis 114, a lateral axis 116, and a vertical axis 118. The length of the wafer processing machine 100 can be defined with respect to the longitudinal axis 114 and the width and the height can be defined with respect to the lateral axis 116 and the vertical axis 118 respectively. The rectangular machine base 112 is longer in the longitudinal axis 114 than its width in the lateral axis 116 and can include a forward longitudinal end 120 and an opposite rearward longitudinal end 122 that are spaced apart with respect to the longitudinal axis 114.

To load and unload semiconductor wafers 102 for processing, the wafer processing machine 100 can include a cassette station 124 located at the forward longitudinal end 120 that can accommodate one or more wafer cassettes 126. The wafer cassettes 126 can be configured to hold a plurality of individual semiconductor wafers 102 on flat, horizontal shelves that are vertically stacked within an enclosure for protection and to facilitate handling and transportation. In an embodiment, the cassette station 124 can be configured to accommodate two wafer cassettes 126 respectively designated for loading and unloading semiconductor wafers 102 upon the wafer processing machine 100.

To transfer the semiconductor wafers 102 between the plurality of processing stations 110 integrally situated in the machine base 112, the wafer processing machine 100 can include a wafer-transfer robot 130 that is supported by a robot frame 132 over the machine base 112. The wafer-transfer robot 130 includes a cylindrical robot body 134 that is mounted on, and that can rotate with respect to, the robot frame 132. A kinematic arm 136 extends from the cylindrical robot body 134 and can be assembled as a kinematic chain of rigid links and joints that can spatially swing and movably articulate with respect to the coordinate system. The wafer-transfer robot 130 can be located proximate to the forward longitudinal end 120 and adjacent to the cassette station 124 to access the wafer cassettes 126 accommodated therein. To secure a semiconductor wafer 102, the wafer-transfer robot 130 can include an end effector at the distal end of the kinematic arm 136 that may be configured with vacuum securement capabilities. For example, the end effector may include ports disposed therein that are in fluid communication with a vacuum source.

The spatial range of the kinematic arm 136 and the end effector can define a working envelope that enables the wafer-transfer robot 130 to deliver the semiconductor wafers 102 for movement through the plurality of processing stations 110 disposed at fixed locations about the machine base 112. The ability of the cylindrical robot body 134 to rotate with respect to the robot frame 132 enables the wafer-transfer robot 130 to direct the kinematic arm 136 either forward or rearward with respect to the longitudinal axis 114 and to either lateral side with respect to the lateral axis 116.

To ensure that the semiconductor wafers 102 are properly oriented as they proceed through the wafer processing machine 100 for processing by the plurality of processing stations 110, the wafer processing machine 100 can include an alignment station 140 that is located proximate to the forward longitudinal end 120 of the machine base 112. The alignment station 140 can be laterally offset from the longitudinal axis 114 and in close proximity to the cassette station 124 to enable the wafer-transfer robot 130 to move the semiconductor wafers 102 from the wafer cassettes 126. The alignment station 140 can include an alignment tray 142 or plate onto which the semiconductor wafers 102 can be set by the wafer-transfer robot 130 to verify alignment, for example, by registering the flat 108 on the peripheral wafer edge 106 or by an optical technique.

In an embodiment, to clean the processed semiconductor wafers 102 after being transferred through and operated upon by the other integrated processing stations 110, the wafer-processing machine 100 can include a cleaning station 144 laterally opposite from the alignment station 140 with respect to the lateral axis 116 and offset from the longitudinal axis 114, and that and can be likewise located proximate to the forward longitudinal end 120 of the machine base 112 within the reach of the wafer-transfer robot 130. Processed semiconductor wafers 102 can be cleaned by the cleaning station 144 prior to being returned by the wafer-transfer robot 130 to the wafer cassettes 126 at the cassette station 124 for offloading and removal. The cleaning station 144 can discharge jets of water or cleaning solvent to wash away debris, including dislodged grinding particulate and semiconductor material removed during the surface processing of the semiconductor wafer 102. To prevent spray, the cleaning station 144 can include an enclosure 146, and the cleaned semiconductor wafers can be spun-dried within the enclosure 146.

To remove material from one of the planar surfaces 104 of the semiconductor wafers 102, the wafer processing machine 100 can include one or more wafer grinding stations that may be located proximate toward the rearward longitudinal end 122 of the machine base 112. In the illustrated embodiment, the wafer processing machine 100 can include a first wafer grinding station 150 and a second wafer grinding station 152 that may be designated for grinding processes that may be conducted on the same semiconductor wafer 102, for example, a rough grinding operation and a fine or finish grinding operation. The rough and fine grinding operations may be differentiated by the material removal rates and by the surface finish produced by the first and second wafer grinding stations 150, 152 respectively. For example, a grinding wheel 154 associated with the first wafer grinding station 150 can have an abrasiveness grade or coarseness greater than a grinding wheel 155 associated with the second wafer grinding station 152. The difference in grade or coarseness of the grinding wheels can be associated with different classes of grinding operations. In other embodiments, the wafer grinding stations 150, 152 of the wafer processing machine 100 can be included in different numbers and/or can be configured for simultaneous processing of multiple semiconductor wafers 102.

Wafer grinding is characterized by using abrasive particles embedded in the grinding wheels 154, 155 to mechanical remove material from the faces 104 of the semiconductor wafers 102 and results in thinning and dimensional changes to the wafer thickness. The inclusion of first and second wafer grinding stations 150, 152 provides other advantages in that either station may be used for coarse or rough grinding. In other embodiments, the grinding wheels 154 or 155 associated with the wafer grinding stations 150, 152 can both be designated for coarse grinding operations or fine grinding operations. In another embodiment, the wafer grinding stations 150, 152 can be arranged to conduct the same grinding processing on two semiconductor wafers 102 simultaneously.

The wafer grinding stations 150, 152 may be substantially identical and include the same features. In an embodiment, the wafer grinding stations 150, 152 each may include a spindle column 156 projecting upright from the machine base 112 with respect to the vertical axis 118. The spindle columns 156 can each accommodate a grinding spindle 158 that is aligned on a grinding spindle axis 159 that extends parallel with the vertical axis 118. Also, as dictated by processing requirements, the grinding spindle columns 156 may accommodate tilting of the grinding spindle axes 159 relative to the vertical axis 118.

The grinding wheels of each of the wafer grinding stations 150, 152 can be attached at the lower distal end of the respective grinding spindles 158, directed toward and spaced above the machine base 112, and the connected grinding wheel spindles 158 can be rotated around the grinding spindle axis 159 relative to the machine base 112. To enable rotation, the grinding spindles 158 are operatively connected to spindle columns 156 by journal bearings. The spindle columns 156 can accommodate hydraulic or electric motors to drive rotation. The spindle columns 156 can be structurally configured for rigidity and stiffness during a grinding operation.

To move a semiconductor wafer 102 to or between the first and second wafer grinding stations 150, 152, for example, between rough and fine grinding operations, the wafer processing machine 100 can include a rotary indexing table 160. The rotary indexing table 160 can be disposed in the machine base 112 generally mid-length between the forward and rearward longitudinal ends 120, 122. In an embodiment, the rotary indexing table 160 can be centrally disposed within the machine base 112 proximate the intersections of the longitudinal axis 114 and the lateral axis 116. The rotary indexing table 160 can also be situated in operative proximity to the first and second wafer grinding stations 150, 152 that are located longitudinally rearward with respect to the longitudinal axis 114. The rotary indexing table 160 can be generally circular in shape and can protrude upwardly from the upper surface of the machine base 112 to define a flat, planar upper table surface that is opposed to and vertically spaced from the grinding wheels 154 and 155 of the first and second wafer grinding stations 150, 152.

The rotary indexing table 160 is rotatable, in either the clockwise or counterclockwise directions, with respect to the machine base 112 about a central table axis 164 parallel to the vertical axis 118 and spatially fixed with respect to the coordinate system. In an embodiment, the first and second wafer grinding stations 150, 152 can be angularly spaced apart 120° from each other with respect to the central table axis 164 and the indexing angle of rotation of the rotary indexing table 160 can correspond to 120°. The rotary indexing table 160 can be operatively connected to the machine base 112 by roller bearings or the like to rigidly support and transfer loads during the grinding process. The secure the rotary indexing table 160, one or more upwardly directed clamps 166 can be situated on the machine base 112 about the circumference of the rotary indexing table 160. When hydraulically actuated, the clamps 166 can engage and lock the rotary indexing table 160 with respect to the machine base 112 to prevent rotation during grinding.

To releasably hold the semiconductor wafers 102, the rotary indexing table 160 can include one or more wafer-holding chucks 170 that vertically protrude from the indexing table surface 162. In the illustrated embodiment, three wafer-holding chucks 170 are angularly spaced at 120° with respect to the central table axis 164 so that the rotary indexing table 160 can concurrently accommodate and transfer three semiconductor wafers through the grinding processes.

The wafer-holding chucks 170 can each include a cylindrical chuck body 172 vertically protruding from the indexing table surface 162 to establish an upright chuck face 174 that is parallel to and vertically spaced above the upper table surface. Each of the upright chuck faces 174 is planar and is configured to make supporting contact with one of the planar wafer surfaces 104 of a semiconductor wafer 102 set thereon. To releasably hold the semiconductor wafers 102, the upright chuck faces 174 can be planar surfaces with suction or vacuum ports in fluid communication with a vacuum source to secure the semiconductor wafers 102.

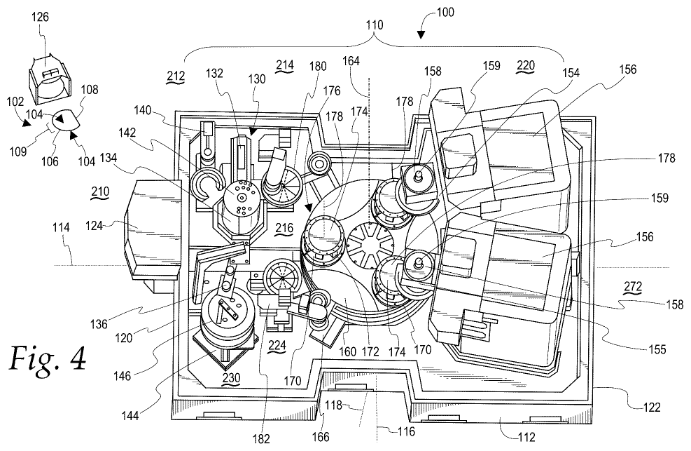

In this regard, as best seen in FIG. 4, with the rotary indexing table 160 positioned with a wafer-holding chuck 170 in operative alignment with each of the grinding wheels 154 and 155 of the wafer grinding stations 150, 152, the third wafer-holding chuck is aligned with the longitudinal axis 114 bisecting chuck face 174. This position associates the wafer-holding chuck with respect to the kinematic arm 136 of wafer-transfer robot 130 for delivery of a wafer to, or recovery from, the wafer-holding chuck as discussed further below. This location, designated 176 in the drawings, is the wafer loading/unloading position discussed further below.

In an embodiment, to conduct the grinding operations, the wafer-holding chucks 170 can be configured to counter-rotate the semiconductor wafers held thereon with respect to the grinding wheels 154, 155 of the respective wafer grinding stations 150, 152. The wafer-holding chucks 170 can each include an internal chuck spindle that is rotatably accommodated by, for example, journal bearings inside the cylindrical chuck body 172 extending from the upper table surface. The internal chuck spindles can each spin about a chuck spindle axis 178 that is parallel with the vertical axis 118. In the illustrated embodiment with three wafer-holding chucks 170, the corresponding three chuck spindle axes 178 can be spaced around the central table axis 164 angularly spaced apart at 120°. The chuck spindles can be made to rotate with respect to the cylindrical chuck bodies 172 by hydraulic or electrical motors disposed in the rotary indexing table 160. In the embodiments wherein the wafer-holding chucks 170 are able to counter-rotate, the wafer-holding chucks 170 and the grinding wheels 154, 155 of the first and second wafer grinding stations 150, 152 can be counterrotated with respect to each other to improve the speed and rate of the grinding or other wafer processing process.

In an embodiment, to perform optional pre- and/or post-grinding operations on the semiconductor wafers 102, the wafer processing machine 100 can include one or more auxiliary processing stations among the plurality of processing stations 110. For example, in the illustrated embodiment, a first auxiliary processing station 180 and a second auxiliary processing stations 182 can be situated longitudinally between the cassette station 124 and the first and second wafer grinding stations 150, 152 to receive the semi-conductor wafer 102 passing there between. The first and second auxiliary processing stations 180, 182 are thus situated in the workflow path and are located within the working envelop of the wafer-transfer robot 130. The first auxiliary processing station 180 may receive semiconductor wafers 102 from the alignment station 140 prior to undergoing a grinding operation and the second auxiliary processing station 182 may receive wafers 102 after a grinding operation and prior to entry into the cleaning station 144; however, in other embodiments, the workflow direction to and from the auxiliary processing stations may be different, and one or both of the auxiliary processing stations may, or may not be used.

The first and second auxiliary processing stations 180, 182 can be integrated and fixedly mounted into the machine base 112 and can be located longitudinally forward of the rotary indexing table 160 and laterally offset on opposite sides of the longitudinal axis 114. In another embodiment, the first and second auxiliary stations 180, 182 can be removable from the machine base 122, enabling modular auxiliary stations structurally configured for different wafer processing operations to be selectively switched into and out of the wafer processing machine 100, or one or both of the auxiliary processing stations 180, 182 may be omitted altogether.

In an embodiment, the first auxiliary processing station 180 is operatively and spatially associated with the alignment station 140 and the second auxiliary processing station is operatively and spatially associated with the cleaning station 144. The structural components of the first and second auxiliary processing stations 180, 182 can protrude upright from the upper surface of the machine base 112 with respect to the vertical axis 118 to enable access from the kinematic arm 136 of the wafer-transfer robot 130. The first and second auxiliary processing stations 180, 182 are advantageously positioned to conduct pre-grinding and/or post-grinding operations on the semiconductor wafers 102 as they are transferred among the plurality of processing stations 110.

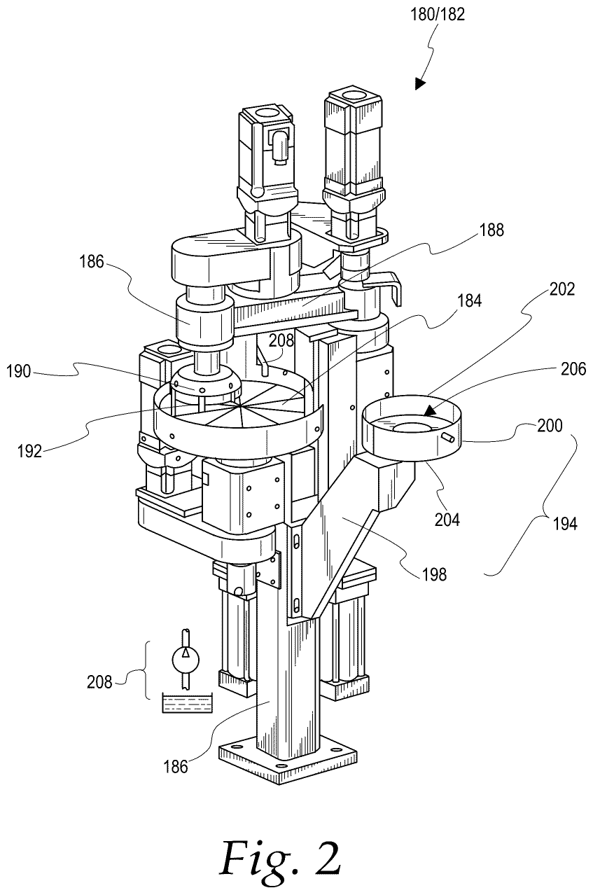

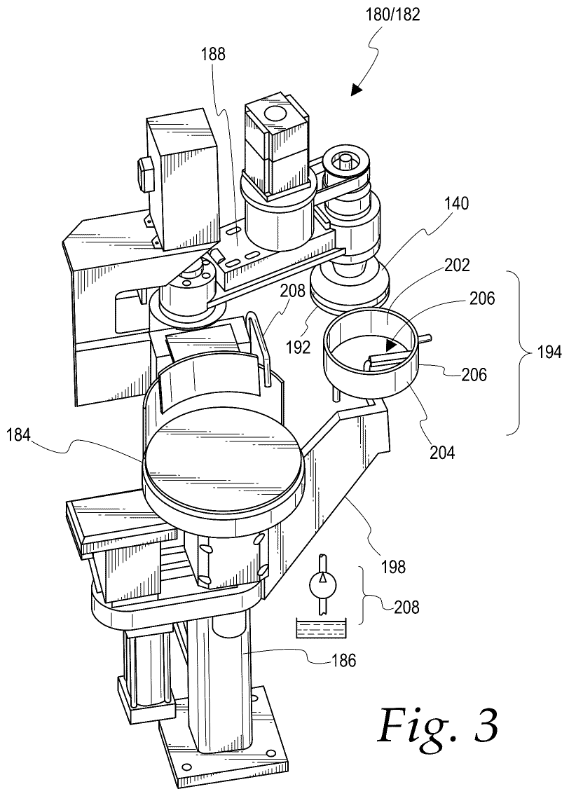

Referring to FIGS. 2 and 3, the first and second auxiliary processing stations 180, 182 can be substantially similar in structure, although in other examples the auxiliary processing stations 180, 182 can be unique in construction and functionality. The first and second auxiliary processing stations 180, 182 can be structurally configured for locating and holding the semiconductor wafers 102 with a high degree of accuracy and repeatability. In an embodiment, the auxiliary processing stations 180, 182 can be configured to conduct additional surface processing of the planar wafer surfaces 104 of the semiconductor wafers 102 before and/or after the main grinding processes conducted by the grinding stations 150, 152.

To support the semiconductor wafer 102 during auxiliary surface processing, the auxiliary processing stations 180, 182 can include a wafer support plate 184 that is planar and circular in shape. The wafer support plate 184 can be situated in a plane parallel to the longitudinal and lateral axes 114, 116 supported by an auxiliary processing station frame 186 that generally extends upright with respect to the vertical axis 118. The wafer support plates 184 are thus spaced above the machine base 112. The wafer support plates 184 can be fixedly mounted to the auxiliary processing station frame 186, although in possible embodiments, it can be configured for rotation relative to the frame while supporting the semiconductor wafer 102. In other possible embodiments, to securely hold the semiconductor wafer 102 during auxiliary processing, the wafer support plate 184 can be configured with ports 185 in communication with a vacuum or suction system of the machine 100.

The auxiliary processing stations 180, 182 can also include a processing arm 188 that is pivotally connected to the auxiliary processing station frame 186 and that is generally located vertically above the wafer support plate 184. A rotatable tool 190 can be attached to the distal end of the processing arm 188, which can be positioned over the wafer support plate 184 by pivotally articulating it with respect to the auxiliary processing station frame 186. During auxiliary processing, the rotatable tool 190 can be swung over and lowered into contact with a semiconductor wafer 102 positioned on the wafer support plate 184, as shown in FIG. 2. The rotatable tool 190 can be rotated relative to the semiconductor wafer 102 and can include an attached tool pad 192 that is configured to conduct a surface process operation such as lapping and/or polishing of the planar wafer surface 104. To cause rotation of the rotatable tool 190 and attached pad 192, an electric motor can be disposed on the processing arm 188 and coupled by a belt or the like with the rotatable tool 190. After processing, the processing arm 188 can be pivoted away from the wafer support plate 184, as shown in FIG. 3, so that the processed semiconductor wafer 102 can be removed by the wafer-transfer robot 130.

To remove material from the semiconductor wafer, the rotatable tool 190 or the attachable tool pad 192 include abrasive material preferably harder than the semiconductor material. During processing of numerous semi-conductor wafers 102, the attachable tool pad 192 of the rotatable tool 190 may become dull or worn, especially for example during lapping operations. To periodically refurbish the attachable tool pad 192, the auxiliary processing stations 180, 182 can each include a dressing station 194. The dressing stations 194 may include support rail 198 extending upright from the auxiliary processing station frame 186 that supports a dressing platform 200. The support rail 198 may further extend angularly from the auxiliary processing station frame 186 to offset the dressing platform 200 from the wafer support plate 184.

The dressing platform 200 may include a circumferential wall 202 extending upright from a planar platform base 204 to define a circular platform cavity 206. During periodic redressing of the attachable tool pad 192, the processing arm 188 can be pivoted to move the rotatable tool 190 over the dressing platform 200 and vertically lowered into cavity 206 to place the surface of pad 192 into operative contact with planar platform base 204. The rotatable tool 190 can be rotated relative to the dressing platform base 204, which may include an abrasive material for refurbishing the tool pad 192.

Referring to FIGS. 2 and 3, in an example, one or both of the first and second auxiliary stations 180, 182 can be configured to utilize an additional abrasive solution or slurry during operation. To introduce the slurry or solution for interaction between the wafer held on the wafer support plate 184 and the rotatable tool 190, the first and/or second auxiliary stations 180, 182 can each be operatively associated with a slurry introduction system 208. The introduction of additional slurry results in the auxiliary stations 180, 182 conducting a three-body interaction as part of the pre- or post-grinding operations performed on the wafers. Because the particles are free to rotate, there are additional degrees of freedom in the way that the abrasives interact with the workpiece surface.

The slurry introduction system 208 can store and deliver a liquid slurry, which may comprise abrasive particles suspended in a liquid medium, to the wafer support plate 184 where the wafers interact with the rotatable tools 190. The slurry introduction system 208 can include a reservoir or tank to accommodate the liquid slurry or solution, one or more slurry conduits such as flexible hoses or rigid pipes or tubing, a pump or similar device to pressurize and direct the slurry, and a discharge nozzle that is oriented to the wafer support plate 184. Moreover, in an embodiment, the slurry introduction system 208 can be configured to return the discharge slurry or solution from proximate the wafer support plate 184 to the reservoir or tank for recirculation.

In an example, the slurry introduction system 208 can be integrally constructed as a structural part of the auxiliary processing station frame 186. For example, the slurry conduits can be attached to and extend along the auxiliary processing station frame 186 and the discharge nozzle can be attached approximately above the wafer support plate 184. Because the first and second auxiliary stations 180, 182 are fixed in relation to the machine base 112, opposed to being operatively associated with the rotary indexing table 160 for example, structurally arranging the slurry introduction systems 208 to fluidly communicate a liquid slurry or solution to the wafer support table and possibly to recirculate and recycle the solution is simplified.

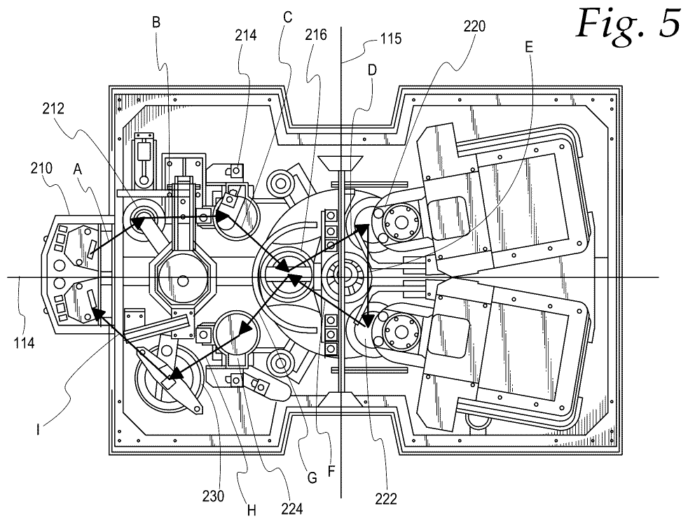

The inclusion of the integral auxiliary processing stations 180, 182 among the plurality of processing stations 110 commonly affixed or integrated into the machine base 112 enables the wafer processing machine 100 to simultaneously conduct a series of multiple different surface processing operations continuously, thereby increasing the processing rate and output of semiconductor wafers 102. For example, referring to FIGS. 4 and 5, and with continued reference to the preceding Figures, there is depicted an exemplary embodiment of the workflow of semiconductor wafers 102 through a plurality of surface processing operations conducted at the plurality of processing stations 110. It will be appreciated that the workflow illustrated is exemplary only, and modifications, alterations, additions, and removal of the plurality of wafer processing steps are contemplated within the scope of the disclosure.

Referring to FIGS. 4 and 5, in a cassette loading/unloading operation designated 210, the wafer-transfer robot 130 can remove a semiconductor wafer 102 from the cassette station 124 located at the forward longitudinal end 120 of the wafer-processing machine 100 and move it to the alignment station 140 for an alignment operation 212, as indicated by arrow A, that places the wafer in the correct orientation for further processing. To conduct an optional pre-grinding operation after the alignment operation designated 212, the wafer-transfer robot 130 can move the semiconductor wafer 102 as indicated by arrow B to the first auxiliary processing station 180 laterally offset from the longitudinal axis 114 for a first auxiliary processing operation designated 214 to be conducted thereon. In an example, the first auxiliary processing operation 214 may be a lapping operation in which one of the planar wafer surfaces 104 is lapped by the rotatable tool 190. For example, with reference to FIGS. 2 and 3, the semiconductor wafer 102 can be placed on the wafer support plate 184 and the processing arm 188 can pivot the rotatable tool 190 and pad 192 over the table and into contact with a planar surface 104 of the wafer. The rotatable tool pad 192 can be made to rotate against the planar surface 104 of the stationary wafer 102 on the wafer support plate 184 during the first auxiliary processing operation 214 to remove material from the planar wafer surface 104 through lapping.

In the example of a lapping operation, the tool pad 192 attached to the rotatable tool 190 can be a pad that incorporates highly abrasive materials such as, for example, diamonds. The lapping operation may be characterized by high contact pressures and rapid material removal rates. In an embodiment, the lapping process can be a wet processes in which an abrasive slurry can be introduced having a coarse abrasive, for example, aluminum oxides suspended in a fluid matrix. The slurry introduction system 208 can be used for introduction of the liquid abrasive slurry. In other embodiments, the lapping process can be a dry process. If the semiconductor wafer 102 was sliced from the semiconductor ingot, the lapping process removes jagged peaks present on the planar wafer surface 104 and can improve parallelism with the opposing surfaces 104 of wafer 102.

After the first auxiliary processing operation 214, the wafer transfer robot 130 can remove the semiconductor wafer 102 from the first auxiliary processing station 180 and deliver it to a wafer-holding chuck 170 of the rotary indexing table 160 as indicated by arrow C. In a chuck loading/unloading operation designated 216, the wafer-transfer robot 130 can position the semiconductor wafer 102 on the wafer-holding chuck 170 that resides along the longitudinal axis 114 of the machine 100 at the chuck loading/unloading position 176, aligned with the longitudinal axis 114 toward the forward longitudinal end 120 of the machine base 112. When rotary indexing table 160 rotates a wafer-holding chuck 170 to the chuck loading/unloading position 176, the particular wafer-holding chuck 170 is situated within the working envelop of the wafer-transfer robot 130. The delivered semiconductor wafer 102 can be secured to the upright chuck face 174 by the suction or vacuum capability of the machine.

In accordance with the illustrated embodiment, the rotary indexing table 160 can rotate clockwise 120° with respect to the central table axis 164 to move the semiconductor wafer 102 held onto the respective wafer-holding chuck 170 to a first grinding operation designated 220 conducted by the first wafer grinding station 150 as indicated by arrow D and, thereafter to a second grinding operation designated 222 conducted by the second wafer grinding station 152 as indicated by arrow E. For example, the first grinding operation 220 can be coarse or rough grinding and the grinding wheel 154 attached to the grinding spindle 158 can be made of a relatively coarse abrasive material for increased removal of material from the semiconductor wafer 102. In contrast, the second grinding operation 222 can be a fine grinding operation and the grinding wheel 155 can be made of a relatively fine abrasive material. In accordance with the versatility of the wafer processing machine, however, the arrangement and workflow direction through the first and second wafer grinding stations are flexible and may be altered.

In the embodiment wherein the wafer-holding chucks 170 include chuck spindles internally contained in the cylindrical chuck bodies 172, the semiconductor wafers 102 secured to the chuck faces 174 can be rotated about the chuck axes 178 relative to the grinding wheels 154 and 155 on the grinding spindles 158, Relative rotation of the grinding wheels 154 and 155 and the faces 104 of wafers 102 on chuck faces 174 enables a range of rotational speeds that can be tailored to the specific surface grinding process and the material of the semiconductor wafers 102. Furthermore, the rotational speeds can be different between the first grinding operation 220 conducted by the first wafer grinding station 150 and the second grinding operation 222 conducted by the second wafer grinding station 152 to be further tailored to the specific grinding process, for example, rough or fine grinding. The rotational speeds of the grinding wheels 154 and 155 can be different between the first and second wafer grinding stations 150, 152. Moreover, in any embodiment, the spindle columns 156 may be tilted as needed to adjust the orientation of the grinding wheels to the wafer surfaces 104.

After the first and second grinding operations 220, 222 have been conducted on the semiconductor wafer 102, the rotary indexing table 160 can again be rotated clockwise 120° with respect to the central table axis 164 to reposition the wafer-holding chuck 170 into the wafer loading/unloading position aligned with the longitudinal axis 114 of the machine base 112 as indicated by arrow F. The wafer-holding chuck 170 is therefore again placed within the working envelop of the wafer-transfer robot 130. The chuck loading/unloading operation 216 can be conducted again by the wafer-transfer robot 130 to remove the semiconductor wafer 102 from the wafer-holding chuck 170.

Notably, the first and second wafer grinding stations 150, 152 of the illustrated machine 100 are located toward the rearward longitudinal end 122 of the machine base 112, outside of the working envelope of the wafer-transfer robot 130. The inclusion of three wafer-holding chucks 170 on the rotary indexing table 160 allows the loading and/or unloading operation of wafer-transfer robot 130 to be conducted concurrently with operation of the wafer grinding stations 150, 152.

In an embodiment, to conduct an optional post-grinding, second auxiliary processing operation designated 224, the wafer-transfer robot 130 can transfer the semiconductor wafer 102 to the second auxiliary processing station 182 as indicated by arrow G. For example, the second auxiliary processing station 182 can be configured for polishing as the second auxiliary processing operation 224 in which the planar wafer surface 104 is polished to a mirror-like finish. With reference to FIGS. 3 and 4, during the polishing operation, the semiconductor wafer 102 is positioned on the wafer support plate 184 and the rotatable tool 190 with pad 192 is swung around by the processing arm 188 to conduct a second auxiliary operation 224.

In an embodiment, the second auxiliary processing station 182 can be configured to introduce a chemical-mechanical slurry during the second auxiliary processing operation to facilitate CMP polishing of the semiconductor wafer 102. For example, the second auxiliary processing station 182 can introduce a CMP slurry chemically configured to react with the semiconductor material and that includes abrasives such as silica of minute particle size. The slurry introduction system 208 can be utilized as part of the CMP operation. The CMP polishing operation may be characterized by a relatively minor material removal rate to enhance precision and accuracy of the final dimensions and finish of the semiconductor wafer 102. In the CMP embodiment, the wafer support plate 184 can, alternatively, be a platen rotatable with respect to the auxiliary processing station frame 186 and can be configured to accommodate a polishing pad. The rotatable tool 190 attached to the processing arm 188 can, alternatively be configured to carry and support the semiconductor wafer 102 with respect to the rotating wafer support plate 184. In an embodiment, the processing arm 188 can oscillate with respect to the rotating wafer support plate 184 to enhance the polishing operation.

After polishing via the second auxiliary processing operation 224, the wafer-transfer robot 130 can move the semiconductor wafer 102 from the second auxiliary processing station 182 to the cleaning station 144 as indicated by arrow H for a cleaning operation designated 230. After the cleaning operation 230, the wafer-transfer robot 130 may retrieve the semiconductor wafer 102 and perform another cassette wafer loading/unloading operation 210 to return the processed semiconductor wafer to the cassette station 124 as indicated by arrow I.

In the embodiments wherein the first and second auxiliary processing stations 180, 182 include a dressing station 194, the rotating tool 190 and pad 192 may be periodically dressed by appropriate movement of the processing arm 188. By periodically redressing the tool pad 192, for example, when the wafer-transfer robot 130 is transferring semiconductor wafers 102 to and from the rotary indexing table 160, the throughput and efficiency of the wafer-processing machine 100 is improved.

As described, the location of the wafer-transfer robot 130 advantageously enables access to the alignment station 140, the first auxiliary processing station 180, the wafer-holding chuck 170 on the rotary indexing table 160 rotated to the chuck loading/unloading position 176, the second auxiliary processing station 182, and the cleaning station 144. The wafer-transfer robot 130 is responsible for automatically transferring the semiconductor wafers 102 through each of the operations within the surface processing workflow associated with the wafer processing machine 100. Moreover, the wafer-transfer robot 130 can be continuously operating to transfer the semiconductor wafers between certain of the processing stations 110 while others of the plurality of processing stations perform surface processing on the wafers, thus efficiency of the wafer-processing machine 100 is optimized, and wafer processing through-put is increased. Advantageously, the embodiment of the wafer processing machine 100 utilizing a single wafer-transfer robot 130 to maneuver the semiconductor wafers 102 through each of the processing stations and operations increases efficiency an throughput while reducing complexity and possibly the cost of the machine.

The machines disclosed herein and the processes carried out thereon include various well known components, features and operating parameters commonly associated with wafer grinding and dressing of the wafer processing tools. Though not specifically discussed, or shown in the accompanying drawings, these elements are considered inherent to the disclosure and fully understood by persons of ordinary skill in the art.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A wafer processing machine for surface grinding a planar semiconductor wafer comprising:
a machine base extending along a longitudinal axis between a forward longitudinal end and a rearward longitudinal end;
a rotary indexing table disposed in and rotatably with respect to the machine base about a central table axis perpendicular to the longitudinal table axis;
a first wafer processing station disposed on and fixed to the machine base and configured to conduct a surface grinding operation on the planar semiconductor wafer and a second wafer processing station disposed on and fixed to the machine base and configured to conduct a second surface grinding operation on the planar semiconductor wafer, the first and second wafer processing stations located between the rotary indexing table and the rearward longitudinal end; and
a first auxiliary processing station disposed on the machine base configured to conduct an auxiliary operation on the semiconductor wafer and a second auxiliary processing station disposed on the machine base configured to conduct a second auxiliary operation on the semiconductor wafer, the first and second auxiliary processing stations located between the rotary indexing table and the forward longitudinal end.

2. The wafer processing machine of claim 1, wherein the first and second wafer processing stations and the first and second auxiliary processing stations are located opposite each other with respect to a longitudinal axis of the machine base.

3. The wafer proceeding machine of claim 2, wherein the rotary indexing table includes a plurality of wafer-holding chucks that can be movably rotated and selectively repositioned for operative alignment with the first wafer processing station, the second wafer processing station, and a wafer loading/unloading position.

4. The wafer processing machine of claim 4, wherein the first and second wafer grinding stations and the first and second auxiliary processing stations are laterally opposite and offset from the longitudinal axis of the machine base.

5. The wafer processing machine of claim 2, wherein the first and second auxiliary processing stations each include a wafer support table and rotating tool that can conduct respectively the first or second auxiliary operation on the semiconductor wafer accommodated on a wafer support table.

6. The wafer processing machine of claim 5, wherein the first and second auxiliary processing stations each include a processing arm attached to the rotatable tool and that pivots with respect to the wafer support table.

7. The wafer processing machine of claim 6, wherein the first and second auxiliary processing stations each include an attachable tool pad that is attachable to the rotatable tool.

8. The wafer processing machine of claim 7, wherein the first and second auxiliary processing stations each include a dressing station for periodically redressing the attachable tool pad.

9. The wafer processing machine of claim 8, wherein the dressing station is supported on a support arm to be vertically coplanar with the wafer support table.

10. The wafer processing machine of claim 2, wherein the first auxiliary processing station is configured to conduct a lapping operation on the semiconductor wafer prior to transfer to the rotary indexing table and the second auxiliary processing station is configured to conduct a polishing operation on the semiconductor wafer after transfer from the rotary indexing table, wherein the first and second auxiliary processing stations are each operatively associated with a slurry introduction system for introduction of a liquid slurry.

11. The wafer processing machine of claim 10, further comprising a wafer-transfer robot for transferring the semiconductor wafer between the wafer loading/unloading position of the rotary indexing table, the first auxiliary processing station, and the second auxiliary processing station.

12. The wafer processing machine of claim 11, further comprising a cassette station located at the forward longitudinal end of the machine base.

13. The wafer processing machine of claim 12, further comprising:
a cleaning station located longitudinally between the second auxiliary processing station and the cassette station; and
an alignment station located longitudinally between the first auxiliary processing station and the cassette station.

14. The wafer proceeding machine of claim 13, wherein the the cassette station, the alignment station, the first auxiliary processing station, the second auxiliary processing station, and the cleaning station are all disposed in a working envelope of the wafer-transfer robot.

15. A method of processing a planar semiconductor wafer through a wafer processing machine comprising:
transferring the semiconductor wafer from a wafer cassette station to an auxiliary processing station for conducting a first auxiliary process with a first rotatable tool;
transferring the semiconductor wafer from the first auxiliary processing station to a wafer-holding chuck on a rotary indexing table;
indexing the rotary indexing table to rotate the semiconductor wafer to a first wafer processing station to conduct a first grinding operation;
indexing the rotary indexing table to rotate the semiconductor wafer to a second wafer grinding station to conduct a second grinding operation;
transferring the semiconductor wafer from the rotary indexing table to a second auxiliary processing station for conducting a second auxiliary process with a second rotatable tool; and
transferring the semiconductor wafer from the second auxiliary processing station to the wafer cassette station.

16. The method of claim 15, wherein the first auxiliary operation is a lapping operation conducted by the first auxiliary processing station on the semiconductor wafer and further comprising the step of introducing a lapping slurry via a slurry introduction system associated with the first auxiliary processing station.

17. The method of claim 16, wherein the second auxiliary operation is a polishing operation conducted by the first auxiliary processing station on the semiconductor wafer and further comprising the step of introducing a polishing slurry via a slurry introduction system associated with the second auxiliary processing station.

18. The method of claim 17, wherein the steps of transferring the semiconductor wafer between the loading/unloading position of the rotary indexing table, the first auxiliary processing station and the second auxiliary processing station is accomplished by a wafer-transfer robot.

19. The method of claim 18, further comprising unloading the semiconductor wafer from a wafer cassette at a cassette station prior to transferring the semiconductor wafer to the first auxiliary processing station and loading the semiconductor wafer to a wafer cassette at the wafer cassette station after transferring the semiconductor wafer from the second auxiliary processing station.

20. The method of claim 19, further comprising periodically dressing the first rotatable tool with a first dressing station supported on the first auxiliary processing stations and periodically dressing the second rotatable tool with a dressing station supported on the second auxiliary processing station.
